(19) United States
(12) Patent Application Publication
(10) Pub. No.: US 2006/0176071 A1
(43) Pub. Date: Aug. 10, 2006

(54) Inspection probe, inspection device for optical panel and inspection method for the optical panel

(75) Inventors: Eiichi Yamagishi, Shiojiri (JP); Akitoshi Maeda, Shiojiri (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/344,819

(22) Filed: Feb. 1, 2006

(30) Foreign Application Priority Data
Feb. 2, 2005 (JP) 2005-026973

(51) Int. Cl. G01R 31/00

(52) U.S. Cl. 324/770

(57) ABSTRACT

An inspection probe for inspecting characteristics of an electronics device having a plurality of signal lines and a drawing portion to which the plurality of signal lines are drawn to be disposed substantially in parallel with each other, the inspection probe being temporarily connected with the signal lines in inspecting the characteristics of the electronics device, the probe including: a board; a plurality of wiring portions provided on the board, the wiring portions extending for a predetermined length in a direction intersecting the drawing direction of the signal lines when the board is pressed to the drawing portion of the signal lines and being arranged in the drawing direction of the signal lines; and contacting sections provided on the wiring portions at a predetermined pitch, the contacting sections being in contact with the signal lines to which a common inspection signal can be inputted when the wiring portions are pressed on the signal lines while being intersected therewith on the drawing portion of the signal lines to electrically connect the signal lines and the wiring portions.

The entire disclosure of Japanese Patent Application No. 2005-26973, filed Feb. 2, 2005, is expressly incorporated by reference herein.

### BACKGROUND

1. Technical Field

The present invention relates to an inspection probe, an inspection device for optical panels and an inspection method for the optical panels.

2. Related Art

There have been known liquid crystal display panels as an optical panel for displaying an image, and a display device 10 having such a liquid crystal display panel 20 as stated and a drive circuit 40 that drives the liquid crystal display panel 20.

FIG. 9 shows an arrangement of the display device 10.

The liquid crystal display panel 20 has liquid crystal cells (not shown) respectively provided to each of pixels on a display surface, thin-film two-terminal elements (switching elements) (not shown) respectively provided to the liquid crystal cells (not shown), a plurality of scanning lines 21 respectively wired on rows of the liquid crystal display panel 20 and a plurality of data lines 22 respectively wired on columns of the liquid crystal display panel 20.

The plurality of data lines 22 and scanning lines 21 are drawn out from the liquid crystal display panel 20 and collectively arranged to a side 31 of a substrate 30.

In FIG. 9, the plurality of data lines 22 are collectively wired substantially in the middle of the side 31 of the substrate 30. Odd scanning lines 21A are arranged on the right of the data lines 22, while even scanning lines 21B are arranged on the left of the data lines 22.

The drive circuit 40 has a scanning line driver (not shown) that sends the scanning lines 21 with a scanning signal that sequentially selects a scanning line 21 and a data line driver (not shown) that sends data signals of the respective pixels on the selected scanning line 21 to the corresponding data lines 22.

Input connector terminals 32 for signal input are provided for the data lines 22 and scanning lines 21 that are arranged to the side of the substrate 30, while output connector terminals 41 for signal output are provided for the drive circuit 40. The output connector terminals 41 are connected with the input connector terminals 32, so that the signals are applied from the drive circuit 40 to the data lines 22 and scanning lines 21. Thereby, an image is displayed on the liquid crystal display panel 20.

Recently, the number of pixels of the liquid crystal display panel 20 has been remarkably increased in order to display a fine image. Along with the increase, a distance between the scanning lines 21 or between the data lines 22 has become smaller and smaller.

In the above-described liquid crystal display panel 20, an image display inspection is conducted for a defect such as an electricity leakage caused by a short between signal lines (scanning lines 21, data lines 22), which normally should be insulated from each other (see, for example, JP-A-2003-66870).

In the image display inspection, an inspection probe 50 is used for sending image inspection signals to the scanning lines 21 and data lines 22, the inspection probe 50 being temporarily connected to the data lines 22 and scanning lines 21. The inspection signals are then applied to the data lines 22 and scanning lines 21 via the inspection probe 50. Thereby, whether the liquid crystal display panel 20 is properly lighted is checked.

FIG. 10 is an enlarged view showing a connecting portion of the inspection probe 50 and the data lines 22. As is obvious, the inspection probe 50 has probe terminals 51 to be connected with terminals 23 of the scanning lines 21 and data lines 22, and when connecting the inspection probe 50 with the scanning lines 21 and data lines 22, each probe terminal 51 of the inspection probe 50 is to be precisely positioned and then connected with the terminal 23 of the scanning lines 21 and data lines 22, as shown in FIG. 10.

In recent years, the liquid crystal display panel 20 that can display a fine image while being compact is demanded, which means that so many pixels need to be arrayed in a small area.

Hence, the distance between the signal lines (scanning lines 21, data lines 22) becomes extremely small. For example, a few hundreds of signal lines are aligned with a pitch of 21 μm (reference numeral g in FIG. 10).

When the signal lines (scanning lines 21, data lines 22) are thus arranged with such a small pitch, the inspection probe 50, which is to be connected with the signal lines (scanning lines 21, data lines 22), needs to be manufactured so as to have the probe terminals with the small pitch.

However, manufacturing the inspection probe 50 having the probe terminals with such small pitch requires a considerable number of processing steps and a huge cost.

For example, when the probe terminal 51 is manufactured by etching, completely preventing defects such as a short in etching with 21 μm pitches requires an enormous cost.

In addition, precisely positioning the terminals with a small pitch (e.g., 21 μm) and respectively connecting with corresponding terminals are highly difficult, which can be carried, for example, by checking on a monitor an image picked by a CCD camera.

Preparing a positioning device with a camera and a monitor also requires a large cost, and the connection work takes a lot of time.

The high cost in the image display inspection of the liquid crystal display panel 20 expands the production cost, while prolonged time for the image display inspection reduces the manufacturing efficiency.

### SUMMARY

An object of the invention is to provide an inspection probe for an optical panel, which can be easily connected to the optical panel; an inspection device for the optical panel, by which the optical panel can be easily inspected; and an inspection method for the optical panel, by which the optical panel can be easily manufactured.

An inspection probe for inspecting characteristics of an electronics device of the aspect of the invention has a plurality of signal lines and a drawing portion to which the plurality of signal lines are drawn to be disposed substantially in parallel with each other, the inspection probe being temporarily connected with the signal lines in inspecting the characteristics of the electronics device, the probe including: a board; a plurality of wiring portions provided on the board, the wiring portions extending for a predetermined length in a direction intersecting the drawing direction of the signal lines when the board is pressed to the drawing portion of the signal lines and being arranged in the drawing direction of the signal lines; and contacting sections provided on the wiring portions at a predetermined pitch, the contacting sections being in contact with the signal lines to which a common inspection signal can be inputted when the wiring portions are pressed on the signal lines while being intersected therewith on the drawing portion of the signal lines to electrically connect the signal lines and the wiring portions.

In the arrangement, a distance between the wiring portions is independent from a pitch of the signal lines, since the wiring portions, which are orthogonal to the signal lines when the board is pressed on the signal lines from above, are provided such that each wiring portion becomes in continuity with the signal lines in which the common inspection signal can be input; and the plurality of wiring portions are allocated in the drawing direction of the signal lines. Thus, the distance between the wiring portions of the inspection probe can be wide for easy processing irrespective of miniaturization of the signal lines. Therefore, the inspection probe can be very easily processed, thereby incredibly reducing manufacturing cost.

In addition, the connection work between the signal lines and the inspection probe can be extremely simple, since each wiring portion can be in continuity with the predetermined signal lines via the contacting sections only by pressing the board of the inspection probe on the data lines in connecting the inspection probe with the signal lines.

An inspection probe for inspecting image display of an optical panel of the aspect of the invention has: columns of pixels exhibiting common one of basic colors, the columns of pixels exhibiting different basic colors being arranged in a row direction in a predetermined order so that more than one basic color are used to display a color image; and a drawing section to which data lines provided to each column for actuating the pixels are drawn to be disposed substantially in parallel with each other, the inspection probe being temporarily connected with the data lines in inspecting the image display of the optical panel, the probe including: a board; a plurality of wiring portions provided on the board, the wiring portions extending for a predetermined length in a direction intersecting the drawing direction of the data lines when the board is pressed to the drawing portion of the data lines and being arranged in the drawing direction of the data lines; and contacting sections provided on the wiring portions at a predetermined pitch, the contacting sections being in contact with the signal lines to which a common inspection signal can be inputted when the wiring portions are pressed on the signal lines while being intersected therewith on the drawing portion of the signal lines to electrically connect the signal lines and the wiring portions.

In the arrangement, where the optical panel is displayed in color by using two or more basic colors (for example, red, green and blue), the optical panel is checked for display unevenness or the like by lighting the optical panel by basic color in the image display inspection of the optical panel. Here, common signals are concurrently input in the data lines for driving the pixels of a common color. For example, all the data lines connecting to red pixels are concurrently input with a common signal.

And, when connecting the inspection probe with the data lines, the board is pressed onto the drawing potion of the data lines. Accordingly, since the wiring portion, which is now set on the board, has the predetermined length in the direction orthogonal to the drawing direction of the data lines, the wiring portion can be on all the data lines so as to be orthogonal to the data lines. The wiring portion is provided with the contacting sections at the predetermined pitch, so that the contacting sections contact the predetermined data lines, i.e., the data lines connecting to the pixels of the common color. Hence, the continuity between the wiring portion and the predetermined data lines is established.

The wiring portion is provided by a plural number with a predetermined distance in the drawing direction of the data lines. For example, the wiring portion is provided for each basic color, so that each wiring portion can be in continuity of the corresponding data lines of the common color.

When an inspection drive signal is input in the wiring portion, the common signal is simultaneously sent to all the data lines connecting to the pixels of the common color via the contacting sections, lighting the optical panel with the predetermined color. In the light-on state, the image display inspection of the optical panel is conducted for a defect such as display unevenness.

Like in related arts, if probe terminals need to be connected with the data lines one by one, the probe terminals become more minute as the pitch of the data lines becomes narrower. With the miniaturization of the data lines, processing cost of the inspection probe will increase, and the connection work between the data lines and the inspection probe will be complicated.

In contrast, according to the aspect of the invention, the distance between the wiring portions is independent from the pitch of the data lines, since the wiring portions, which become orthogonal to the data lines when the board is pressed on the data lines from above, are provided such that each wiring portion becomes in continuity with the data lines in which a common inspection signal can be input; and the plurality of wiring portions are allocated in the drawing direction of the data lines. Thus, the distance between the wiring portions of the inspection probe can be wide for easy processing irrespective of the miniaturization of the data lines. Therefore, the inspection probe can be very easily processed, thereby incredibly reducing manufacturing cost.

In addition, the connection work between the data lines and the inspection probe can be extremely simple, since each wiring portion can be in continuity with the predetermined data lines via the contacting sections only by pressing the board of the inspection probe on the data lines in connecting the inspection probe with the data lines.

Since the inspection probe is manufactured in large quantities, simplifying the connection work, in which the inspection probes are connected to the optical panel one by one, can considerably shorten the total time required for the image display inspection, which presents an incredible effect that contributes to improvement of manufacturing efficiency.

According to the aspect of the invention, preferably, the wiring portions are provided by a number corresponding to the number of the basic colors, and the contacting sections provided on one of the wiring portions are positioned in correspondence with the data lines of common one of the basic colors.

In the arrangement, the wiring portion is provided by the number of the basic colors and each wiring portion has the contacting sections positioned so as to contact the data lines of the corresponding color, so that all the wiring portions can be simultaneously connected with all the data lines of all the colors only by pressing the board on the data lines in the drawing portion.

Hence, it is not necessary to change the inspection probe by to-be-inspected color, but only one attachment of the inspection probe is sufficient for the inspection of the optical panel 20, so that troublesome steps in the connection work can be eliminated, thereby improving inspection efficiency.

According to the aspect of the invention, preferably, the wiring portion has a communication wiring for signals; and an insulation covering that insulatively covers the communication wiring, and the contacting section is formed as a projection protruding from the communication wiring and the insulation covering covers the wiring portion except for an area occupied by the contacting sections.

In the arrangement, since the communication wiring is covered with the insulation covering except for the area on which the contacting sections are provided, the communication wiring does not contact any part other than the predetermined data lines even when the wiring portions are pressed on the data lines. Thus, the inspection signals from the wiring portion are applied only to the predetermined data lines, but not applied to the other wrong data lines, so that the image display inspection can be precisely conducted. Since the contacting section protrudes from the insulation covering, the contacting sections can reliably contact the data lines when the wiring portions are pressed on the data lines, securing the continuity between the communication wirings and the data lines. Consequently, it is possible to prevent an inspection error caused by a contact failure between the wiring portions and the data lines, so that the image display inspection can be appropriately conducted.

Here, the contacting section may preferably be a conductive resilient body that is elastically deformed when being pressed on the data lines.

In the arrangement, the contacting section is deformed so as to wrap around the data line when being pressed on the data lines, so that a contact area between the contacting section and the data line can be widen, thereby reliably establishing the continuity between the contacting section and the data lines. Therefore, the data lines and the wiring portion (communication wiring) can be reliably connected.

According to the aspect of the invention, preferably, the basic colors are red, blue and green, and the optical panel has a sequential repetition of wiring of red data lines for driving red pixels, blue data lines for driving blue pixels and green data lines for driving green pixels, the wiring portions include a red wiring portion to be in common continuity with all the red data lines, a blue wiring portion to be in common continuity with all the blue data lines, and a green wiring portion to be in common continuity with all the green data lines, the red wiring portion has the contacting sections positioned in correspondence with an allocation pitch of the red data lines, the blue wiring portion has the contacting sections positioned in correspondence with an allocation pitch of the blue data lines, and the green wiring portion has the contacting sections positioned in correspondence with an allocation pitch of the green data lines.

In the arrangement, since the inspection probe is provided with the red wiring portion for the red data lines, the green wiring portion for the green data lines and the blue wiring portion for the blue data lines, the image display inspection for red, green and blue can be conducted by connecting the inspection probe of the aspect of the invention with the optical panel that displays an image in color by using the three colors of R, G and B.

The number of the wiring portion provided for one color is not limited to one, but two or more wiring portions may be provided for each color.

In other words, the arrangement of connecting one wiring portion with all the red data lines may not be employed. For example, the red data lines may be divided in two groups with every two data lines as one group. And, a first wiring portion may be connected with a first group of the red data lines, while a second wiring portion may be connected with a second group of the red data lines. When the data lines are thus divided in a plurality of groups such that each group can be input with the inspection signal by the corresponding wiring portion, a detailed image display inspection can be conducted compared to the inspection in which the data lines are simply classified by color.

An inspection probe for inspecting image display of an optical panel of the aspect of the invention has a drawing portion to which common scanning lines for driving pixels for each row are drawn to be disposed substantially in parallel with each other, the inspection probe being in temporal contact with the scanning lines in inspecting in the image display of the optical panel, the probe including: a board; a plurality of wiring portions provided on the board, the wiring portions extending for a predetermined length in a direction intersecting the drawing direction of the scanning lines when the board is pressed to the drawing portion of the signal lines and being arranged in the drawing direction of the scanning lines; and contacting sections provided on the wiring portions, the contacting sections being in contact with the scanning lines to which a common inspection signal can be inputted when the wiring portions are pressed on the scanning lines while being intersected therewith on the drawing portion of the scanning lines to electrically connect the scanning lines and the wiring portions.

In the arrangement, where the optical panel has the scanning lines, the optical panel is inspected for a leakage between the scanning lines by inputting the inspection signal of opposite phases in the scanning lines next to each other. For example, in inputting the inspection signals of opposite phases in the scanning lines next to each other, a certain common signal can be concurrently input in odd scanning lines and another common signal, which is in the opposite phase, can be input in even scanning lines.

When connecting the inspection probe with the scanning lines, the board is pressed onto the drawing potion of the scanning lines. Accordingly, since the wiring portion, which is thus set on the board, has the predetermined length in the direction orthogonal to the drawing direction of the scanning lines, the wiring portion can be on all the scanning lines so as to be orthogonal to the scanning lines. Since the wiring portion is provided with the contacting sections at the predetermined pitch, the contacting sections contact the predetermined scanning lines, i.e., the odd scanning lines or the even scanning lines. Hence, the continuity between the wiring portion and the predetermined scanning lines is established.

When an inspection drive signal is input in the wiring portion, the signal is sent to the scanning lines via the contacting sections, thereby lighting the optical panel on. In the light-on state, the image display inspection of the optical panel is conducted for a defect such as a leakage between the scanning lines.

In the arrangement, since the wiring portions are connected with the scanning lines of the optical panel with the predetermined pitch, by, for example, applying the inspection signals of opposite phases in the scanning lines next to each other, whether a defect such as a leakage is occurred between the scanning lines next to each other can be conducted.

Like in related arts, if probe terminals need to be connected with the scanning lines one by one, the probe terminals become more minute as the pitch of the scanning lines becomes narrower. However, according to the aspect of the invention, the distance between the wiring portions is independent from the pitch of the scanning lines, since the wiring portions, which become orthogonal to the scanning lines when the board is pressed on the scanning lines from above, are provided such that each wiring portion becomes in continuity with the scanning lines with the predetermined pitch; and the plurality of wiring portions are allocated in the drawing direction of the scanning lines. Thus, the distance between the wiring portions of the inspection probe can be wide for easy processing irrespective of miniaturization of the scanning lines. Therefore, the inspection probe can be very easily processed, thereby incredibly reducing manufacturing cost.

In addition, the connection work between the scanning lines and the inspection probe can be extremely simple, since each wiring portion can be in continuity with the predetermined scanning lines via the contacting sections only by pressing the board of the inspection probe on the scanning lines in connecting the inspection probe with the scanning lines.

Since the optical panel is manufactured in large quantities, simplifying the connection work of the inspection probe to the optical panel can considerably shorten the total time required for the image display inspection, which presents an incredible effect that contributes to improvement of manufacturing efficiency.

According to the aspect of the invention, preferably, the number of the wiring portions is two, and the contacting sections provided on one of the wiring portions contact every two scanning lines to establish continuity between the scanning lines and the wiring portion.

In the arrangement, since the two wiring portions are provided and each wiring portion contacts every two scanning lines, the two wiring portions are respectively connected with odd scanning lines and even scanning lines. Hence, if the two wiring portions are respectively input with the inspection signals of opposite phases, the inspection signals of the opposite phases are input in the odd scanning lines and the even scanning lines via the wiring portions, so that the image display inspection can be conducted for a defect such as a leakage between the odd scanning line and the even scanning line.

Note that, when classifying the scanning lines, the arrangement in which the scanning lines are divided in two groups with every two scanning lines as one group may not be employed, but the scanning lines may be classified in three or more groups.

An inspection device of the aspect of the invention has an inspection probe; and an inspection signal transmitter that inputs an inspection drive signal to an optical panel via the inspection probe.

In the arrangement, the similar functions and advantages as the above-described aspects of the invention can be obtained. In detail, the distance between the wiring portions of the inspection probe can be wide for easy processing irrespective of miniaturization of the data lines and scanning lines. Therefore, the inspection probe can be very easily processed, thereby incredibly reducing manufacturing cost.

In addition, the connection work between the signal lines (data lines and scanning lines) and the inspection probe can be extremely simple, since each wiring portion can be in continuity with the signal lines (data lines and scanning lines) via the contacting sections only by pressing the board of the inspection probe on the data lines and the scanning lines in connecting the inspection probe with the data lines and scanning lines.

An inspection method of an optical panel of the aspect of the invention has a connecting step of an inspection probe with the optical panel; and an inputting step of an inspection drive signal to the optical panel via the inspection probe.

In the arrangement, since the connection work to connect the inspection probe with the data lines or the scanning lines is extremely easy in the connecting step, the inspection of the optical panel can be conducted very efficiently.

### BRIEF DESCRIPTION OF THE DRAWINGS

The invention will be described with reference to the accompanying drawings, wherein like numbers reference like elements.

FIG. 1 shows an overall layout in which a liquid crystal display panel to be inspected is set in an inspection device according to a first exemplary embodiment of the inspection device of the invention;

FIG. 2 is a top plan view of an inspection probe according to the first exemplary embodiment;

FIG. 3 shows a connection state where the inspection probe is connected with data lines of the liquid crystal display panel according to the first exemplary embodiment;

FIG. 4 is an enlarged view of a contacting portion where the inspection probe contacts the data lines according to the first exemplary embodiment;

FIG. 5 is a cross section of the inspection probe according to the first exemplary embodiment;

FIG. 6 is another cross section showing a connection state where the inspection probe is connected with the data lines according to the first exemplary embodiment;

FIG. 7 shows a connection state where an inspection probe is connected with scanning lines of a liquid crystal display panel according to a second exemplary embodiment of the inspection device of the invention;

FIG. 8 shows a connection state where an inspection probe is connected with data lines of a liquid crystal display panel according to a modification 1 of the inspection device of the invention;

FIG. 9 shows an arrangement of a display device; and

FIG. 10 is an enlarged view showing a connecting portion of an inspection probe and data lines according to a related art.

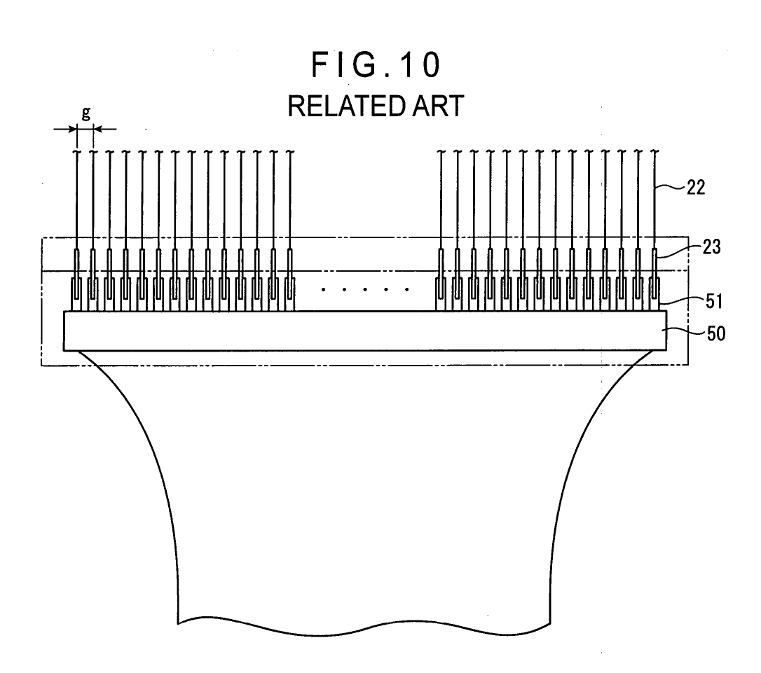

### DESCRIPTION OF EXEMPLARY EMBODIMENT(S)

Exemplary embodiments of the invention will be described below with reference to the attached drawings and the numerals assigned to respective elements shown in the drawings.

### 1 First Exemplary Embodiment

A first exemplary embodiment of an inspection device for optical panels according to the invention will be described.

Before describing the inspection device of the invention, a liquid crystal display panel 20 to be inspected and how to inspect the liquid crystal display panel 20 will be briefly explained.

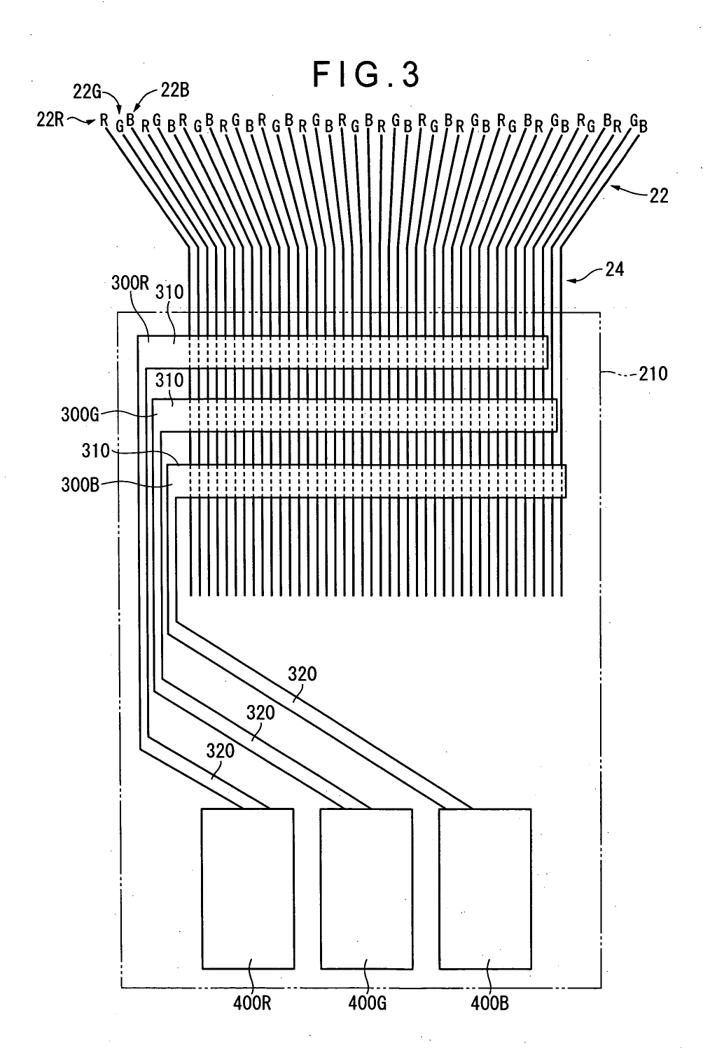

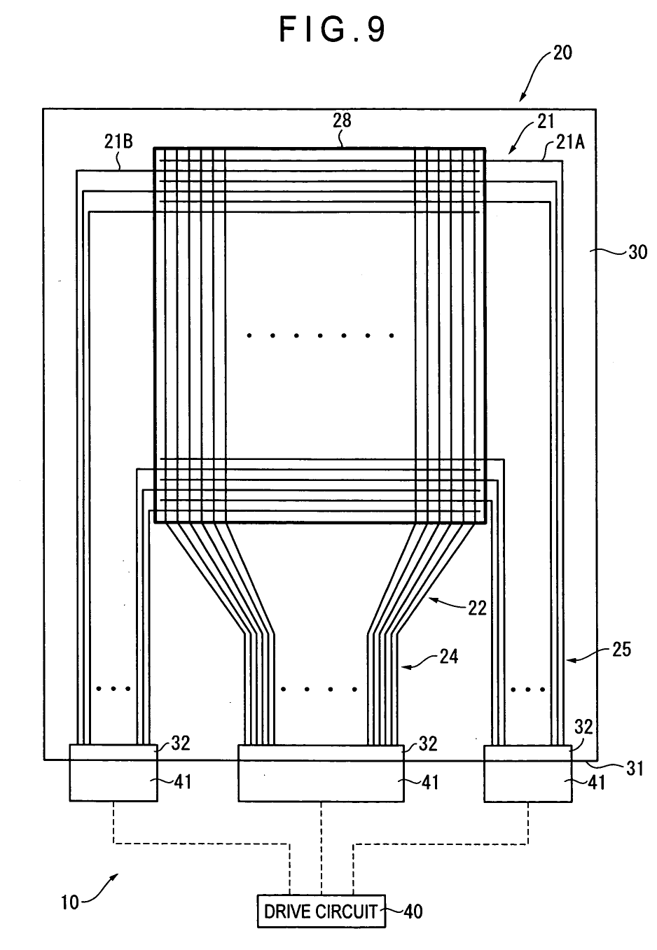

The liquid crystal display panel 20 to be inspected according to the invention is a liquid crystal display panel 20 that: displays an image in colors by using, e.g., R (red), G (green) and B (blue); and has pixels arrayed in rows and columns, the pixels in a common column emitting a common color of R (red), G (green) or B (blue). When seeing in rows, the colors of R (red), G (green) and B (blue) are repeatedly arrayed in this order (see, e.g., FIG. 9 or FIG. 3).

Each pixel has liquid crystal cells (not shown) and thin-film two-terminal elements (switching element) (not shown) respectively provided to the liquid crystal cells. Data lines 22 are longitudinally wired (in columns) in the liquid crystal display panel 20 and scanning lines 21 are laterally wired (in rows) in the liquid crystal display panel 20. In other words, the pixels in a common row are connected by a common scanning line 21, while the pixels in a common column, which are the pixels emitting a common color, are connected by a common data line 22.

Hereinafter, the data line 22 connecting the red pixels is called a red data line 22R, the data line 22 connecting the green pixels is called a green data line 22G, and the data line 22 connecting the blue pixels is called a blue data line 22B.

The data lines 22 and scanning lines 21 are drawn from a display 28 of the liquid crystal display panel 20 and collectively arranged to a side 31 (the bottom side in FIG. 9) of a substrate 30.

In detail, all the data lines 22 are directly drawn from the display 28 of the liquid crystal display panel 20 (e.g., the data lines are drawn downward in FIG. 9), arranged in parallel to each other near the side 31 of the substrate 30 and connected with an input connector terminal 32 on the side 31 of the substrate 30.

Aligning all the data lines 22 in parallel in the vicinity of the side 31 of the substrate 30 forms a drawing portion 24.

The scanning lines 21 are drawn in two opposite ways, depending on whether the scanning line is even or odd. Odd scanning lines 21 are drawn to the right, while even scanning lines 21 are to the left.

Both of the odd scanning lines 21A drawn to the right and the even scanning lines 21B drawn to the left are further extended to the side 31 of the substrate 30 and respectively connected to the input connector terminals 32 on the side 31 of the substrate 30. Again, aligning the scanning lines 21 in parallel in the vicinity of the side 31 of the substrate 30 forms other drawing portions 25.

In an image display inspection of the liquid crystal display panel 20, the pixels can be classified in three color groups of R (red), G (green) and B (blue), so that the liquid crystal display panel 20 is inspected for each of the colors. For example, in a light-on inspection for red, common signals are concurrently sent to all the data lines connecting the red pixels (red data lines 22R) to light the entire liquid crystal display panel with red. In this state, the liquid crystal display panel 20 is checked for a point defect, a line defect or pixel unevenness in terms of red color, and then inspected for a defect such as a short between the data lines based on the found display defects. If there is a defect such as a leakage between one red data line 22R and another data line (green data line 22G or blue data line 22B), the pixel cannot be properly lighted on, and thereby the defect can be detected.

Similarly, in a light-on inspection for green, common signals are concurrently sent to all the green data lines 22G to light the entire liquid crystal display panel with green, while in a light-on inspection for blue, common signals are concurrently sent to all the blue data lines 22B to light the entire liquid crystal display panel with blue.

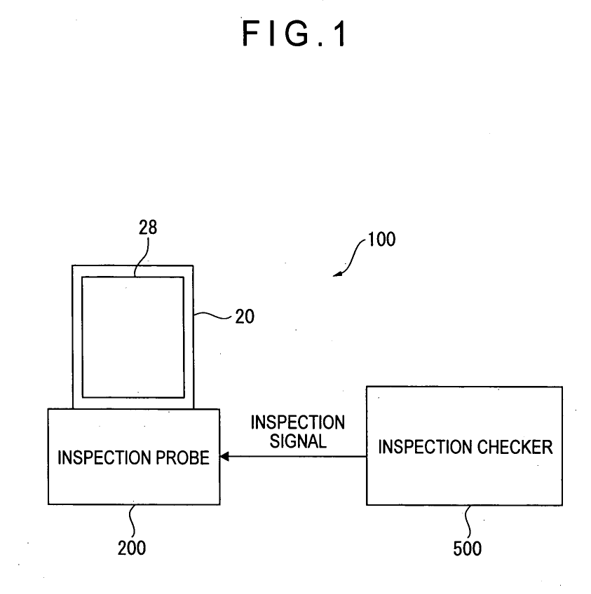

Now, the first exemplary embodiment of the inspection device for optical panels according to the invention will be described with reference to FIGS. 1 to 6.

FIG. 1 shows an overall layout in which the liquid crystal display panel 20 to be inspected is set in the inspection device.

An inspection device 100 has an inspection probe 200 that is temporarily connected with the liquid crystal display panel 20 in an image display inspection of the liquid crystal display panel 20, and an inspection checker (inspection signal transmitter) 500 that inputs an inspection drive signal into the liquid crystal display panel 20 via the inspection probe 200.

The inspection device 100 may also have a CCD camera as an image pickup that picks a display image of the liquid crystal display panel 20, an image processor that automatically conducts an image display inspection of the liquid crystal display panel based on image data from the CCD camera, or the like.

An arrangement of the inspection probe 200 will be explained. Although both of the data lines 22 and scanning lines 21 are connected with the liquid crystal display panel 20, the inspection probe 200 that connects with the data lines 22 of the liquid crystal display panel 20 is primarily explained in the present exemplary embodiment.

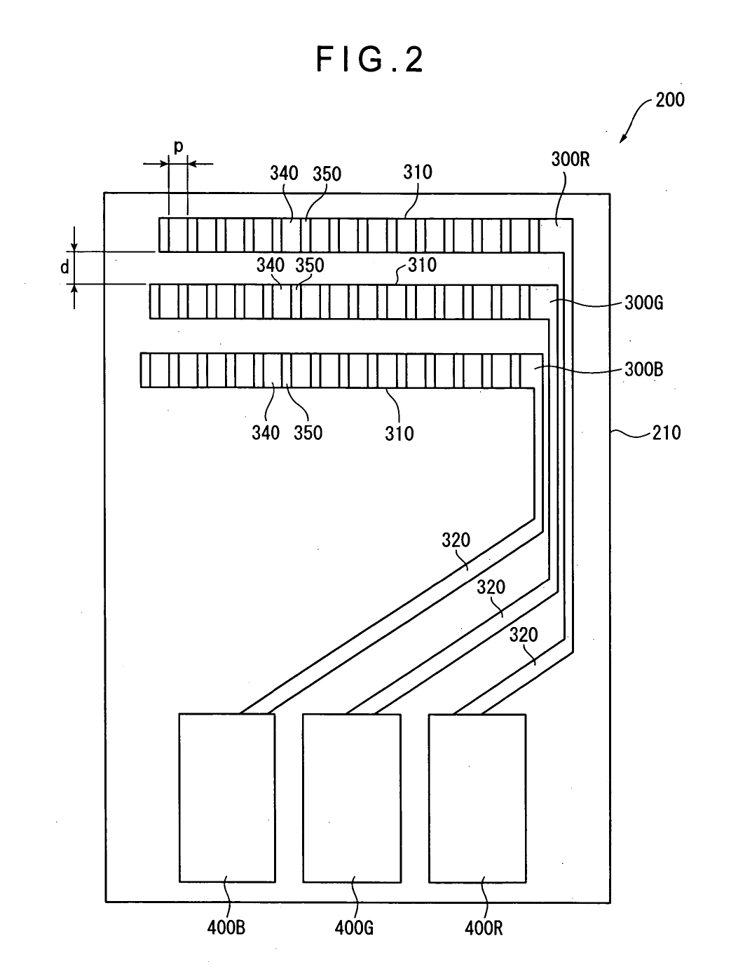

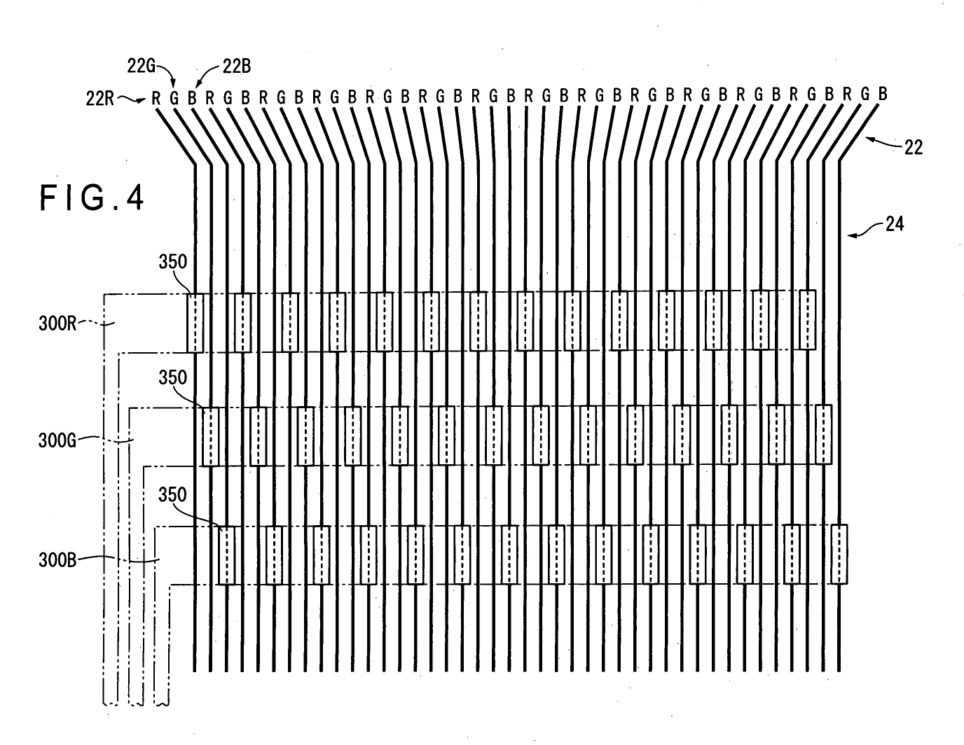

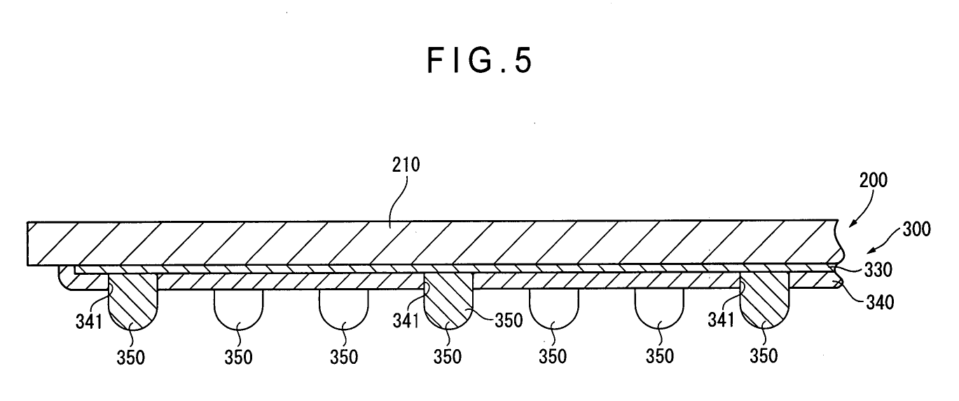

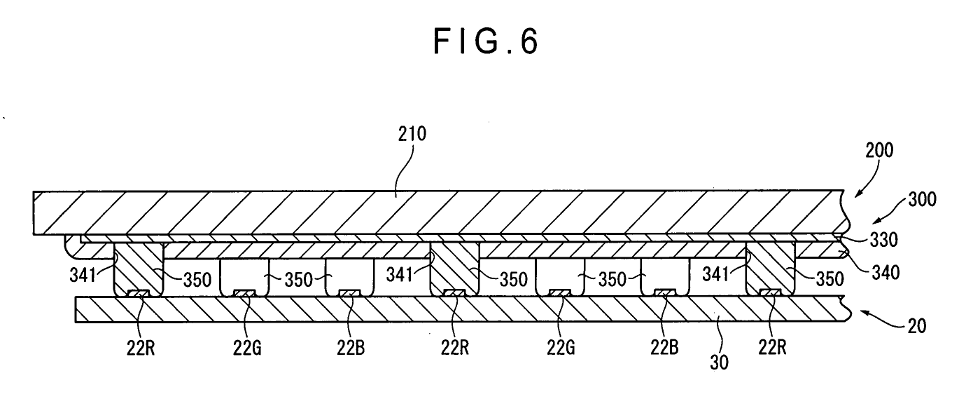

FIG. 2 is a top plan view of the inspection probe 200. FIG. 3 shows a connection state where the inspection probe 200 is connected with the data lines 22 of the liquid crystal display panel 20. FIG. 4 is an enlarged view of a contacting portion where the inspection probe 200 contacts the data lines 22. FIG. 5 is a cross section of the inspection probe 200. And, FIG. 6 is a cross section showing a connection state where the inspection probe 200 is connected with the data lines 22.

The inspection probe 200 is pressed on the data lines 22 in the drawing portion 24 from above (see FIG. 3) into connection with all the data lines 22 to establish continuity (see FIG. 4).

The inspection probe 200 has a board 210; three wiring portions 300R, 300G and 300B disposed on the board 210; and signal input pads 400R, 400G and 400B respectively provided in correspondence with the wiring portions 300R, 300G and 300B, the signal input pads 400R, 400G and 400B being input with drive signals from the inspection checker 500.

The three wiring portions 300R, 300G and 300B are respectively a red wiring portion 300R, a green wiring portion 300G and a blue wiring portion 300. FIG. 2 shows the red wiring portion 300R, the green wiring portion 300G and the blue wiring portion 300B in this order from top.

When the three wiring portions of the red wiring portion 300R, the green wiring portion 300G and the blue wiring portion 300B are provided, a distance d between the adjacent wiring portions is not particularly limited. The distance d may be wide for easy processing, for example, about 40 μm.

When the wiring portions 300R, 300G and 300B are pressed on the drawing portion 24 of the data lines 22 from above (see FIG. 9), the wiring portions come in connection with the respective data lines 22R, 22G and 22B to establish continuity.

Namely, the red wiring portion 300R simultaneously comes in connection with all the red data lines 22R of the liquid crystal display panel 20 to establish continuity. In the same way, the green wiring portion 300G simultaneously comes in connection with all the green data lines 22G of the liquid crystal display panel 20 to establish continuity, while the blue wiring portion 300B simultaneously comes in connection with all the blue data lines 22B of the liquid crystal display panel to establish continuity (see FIG. 4).

The respective wiring portions 300R, 300G and 300B have a main shaft section 310 laterally and linearly extended at an upper portion of the board 210 in FIG. 2 and a coupling shaft section 320 drawn downward from one end of the main shaft section 310 to be further extended obliquely downward at about 45 degrees. Lower ends of the coupling shaft sections 320 are respectively connected with the red signal input pad 400R, the green signal input pad 400G and the blue signal input pad 400B.

A cross sectional structure of the wiring portions 300R, 300G and 300B will be described.

The respective wiring portions 300R, 300G, and 300B have a conductive wiring (communication wiring) 330 disposed on the board 210; an insulating film 340 that electrically insulates to protect the communication wiring 330; and contacting sections 350 that are provided with a predetermined pitch in the main shaft section 310 (see, e.g., FIG. 5).

The communication wiring 330 is wired all along the signal input pads 400R, 400G and 400B, the coupling shaft sections 320 and the main shaft sections 310.

The insulating film 340 is provided over the coupling shaft section 320 and the main shaft section 310 of the communication wiring 330, the insulating film 340 being provided with clearances 341 formed at a predetermined pitch in the main shaft section 310.

Positions of the clearances 341 correspond to the distance between the data lines 22R, 22G or 22B, with which the wiring portions 300R, 300G or 300B are respectively connected. For example, in the red wiring portion 300R, the clearances 341 in the insulating film 340 are formed with the pitch corresponding to the pitch of the red data lines 22R. The insulating film 340 may be formed of polyimide.

The contacting section 350 is formed as a projection protruding from the communication wiring 330 in the main shaft section 310, at least the tip end of the contacting section 350 being protruding from the insulating film 340.

The contacting section 350 is a conductive resilient body with a round tip end in a normal condition (see FIG. 5). When pressed onto the data line 22R, 22G or 22B, the contacting section 350 is flexibly and resiliently deformed to wrap around the data line 22R, 22G or 22B, thereby widening a contact area (see FIG. 6).

When the inspection probe 200 is pressed on the data lines 22R, 22G or 22B from above, a plurality of the contacting sections 350 provided to one of the wiring portions (300R, 300G or 300B) simultaneously contact all the data lines of a common color (22R, 22G or 22B) to establish continuity between all the data lines of the common color (22R, 22G or 22B) and the communication wiring 330. Specifically, the contacting sections 350 in, for example, the main shaft section 310 of the red wiring portion 300R are respectively provided for all the red data lines 22R. The contacting sections 350 of the green wiring portion 300G are respectively provided for all the green data lines 22G. And, the contacting sections 350 of the blue wiring portion 300B are respectively provided for all the blue data lines 22B (see FIG. 4).

In other words, since the data lines 22R, 22G and 22B are arranged in this order repeatedly, in a case of the red wiring portion 300R, the contacting sections 350 are provided so as to contact all the red data lines 22R by skipping the green data lines 22G and the blue data lines 22B. Hence, the contacting sections 350 are disposed at a pitch p, which is three times as large as the allocation pitch of the data lines 22 (e.g., 20 μm), accordingly the pitch p being 60 μm.

As shown in FIG. 5, when the main shaft section 310 of the red wiring portion 300R is cut in cross section in the axial direction, the contacting sections 350, which are to contact the red data lines 22R, are arranged next to each other with intervals filled by the insulating film 340.

The green wiring portions 300G and the blue wiring portions 300B have the contacting sections 350 with the same interval as the red wiring portions 300R. The contacting sections 350 of the green wiring portions 300G and of the blue wiring portion 300B are respectively displaced to the right and the left from the red wiring portions 300R by a width of one data line such that the contacting sections 350 of the green wiring portions 300G and of the blue wiring portion 300B respectively contact the green data lines 22G and the blue data lines 22B at the same time when the contacting sections 350 of the red wiring portions 300R contact the red data lines 22R.

The signal input pads 400R, 400G and 400B are located at a lower portion of the board 210 next to each other. Specifically, the red signal input pad 400R, the green signal input pad 400G and the blue signal input pad 400B are allocated in this order from right in FIG. 2.

The red signal input pad 400R, the green signal input pad 400G and the blue signal input pad 400B are respectively connected with the red wiring portion 300R, the green wiring portion 300G and the blue wiring portion 300B.

The inspection checker 500 applies inspection signals to the signal input pads 400R, 400G and 400B in turn to drive the liquid crystal display panel 20 for inspection.

How to use the inspection device 100 having the above-described arrangement will be explained.

In the image display inspection of the liquid crystal display panel 20, the inspection probe 200 is attached and connected to the drawing portion 24 of the data lines 22 (connecting step).

In the attachment, the inspection probe 200 is to be pressed on the data lines 22 from above such that the main shaft sections 310 of the wiring portions 300R, 300G and 300B become orthogonal to the data lines 22.

As a result, all the contacting sections 350 come into contact with the predetermined data lines 22, thereby establishing continuity between the communication wiring 330 and the data lines 22.

For example, as shown in FIG. 4 in an enlarged manner, since the contacting sections 350 of the red wiring portion 300R are provided with the same pitch as that of the red data liens 22R, all the contacting sections 350 of the red wiring portion 300R simultaneously contact all the red data lines 22R when the main shaft section 310 of the red wiring portion 300R is pressed on the data lines 22 so as to be orthogonal to the data lines 22.

Similarly, the contacting sections 350 of the green wiring portion 300G contact the green data lines 22G, while the contacting sections 350 of the blue wiring portion 300B contact the blue data lines 22B.

When contacting, the tip end of the contacting section 350 is elastically deformed to wrap around the data line 22, so that the contacting section 350 can contact the data line 22 in a wide area, thereby reliably establishing continuity between the contacting section 350 and the data line 22, as shown in FIG. 6.

In this state, the inspection drive signals are input to the signal input pads 400R, 400B and 400G in turn from the inspection checker 500 (signal inputting step).

For example, when conducting a light-on inspection for red pixels, the drive signals are input only to the red signal input pad 400R.

Then, the input drive signals are input simultaneously to all the red data lines 22R from the red signal input pad 400R via the communication wiring 330 and the contacting sections 350. But, the drive signals are not input to the green data lines 22G and the blue data lines 22B. Therefore, the voltage is applied to the red pixels via the red data lines 22R, lighting all the red pixels on.

The image display inspection for red is conducted by inspection personnel by checking the light-on state with eyes or based on an image picked by the CCD camera. Subsequently, the light-on inspections for green and blue are conducted in turn.

When the image display inspection has been finished, the inspection probe 200 is removed from the data lines 22. Good liquid crystal display panels are sent for a next manufacturing step.

The following advantages can be obtained according to the first exemplary embodiment that has the above-stated arrangement.

(1) Since the wiring portions 300R, 300G and 300B, which are provided so as to be orthogonal to the data lines 22 when the inspection probe 200 is pressed on the data lines 22 from above, can collectively come into continuity with the corresponding data lines of the common color (22R, 22G or 22B), and the wiring portions 300R, 300G and 300B are allocated with the distances in the drawing direction of the data lines 22, the distance d between the wiring portions (300R, 300G, 300B) can be independent from the allocation pitch of the data lines 22. Thus, the distance between the wiring portions 300R, 300B and 300G of the inspection probe 200 can be wide for easy processing irrespective of miniaturization of the data lines 22. Therefore, the inspection probe 200 can be very easily processed, thereby incredibly reducing manufacturing cost.

(2) Since the wiring portions 300R, 300G and 300B can be in continuity with the predetermined data lines 22R, 22G and 22B via the contacting sections 350 only by pressing the board 210 of the inspection probe 200 on the data lines 22 in connecting the inspection probe 200 with the data lines 22, the connection work of the data lines 22 and the inspection probe 200 can be extremely simple.

Since the liquid crystal display panel 20 is manufactured in large quantities, simplifying the connection work of the inspection probe 200 to the liquid crystal display panel 20 can considerably shorten the total time required for the image display inspection, which is an incredible effect that contributes to improvement of manufacturing efficiency.

(3) Since the same number of the wiring portions 300R, 300G and 300B as the basic color (R, G, B) are provided and the wiring portions 300R, 300G and 300B have the contacting sections 350 so positioned as to respectively contact the data lines 22R, 22G and 22B, only by pressing the board 210 on the drawing portion 24 of the data lines 22, the wiring portions 300R, 300G and 300B can be simultaneously connected with the data lines of all the colors, i.e., 22R, 22G and 22B.

Hence, it is not necessary to change the inspection probe 200 by to-be-inspected color and only one attachment of the inspection probe 200 is enough for the inspection of liquid crystal display panel 20, so that troublesome steps in the connection work can be eliminated, thereby improving inspection efficiency.

(4) Since the communication wiring 330 is covered with the insulating film 340 except for the area on which the contacting sections 350 are provided, the communication wiring 330 does not contact any part other than the predetermined data lines even when the wiring portions 300R, 300G and 300B are pressed on the data lines 22. Thus, the inspection signals from the wiring portion 300 are applied only to the predetermined data lines 22, not to the other data lines 22 by accident, so that the image display inspection can be precisely conducted.

(5) Since the contacting section 350 protrudes from the insulating film 340, the contacting sections 350 can reliably contact the data lines 22 when the wiring portions 300R, 300G and 300B are pressed on the data lines 22, securing the continuity between the communication wirings 330 and the data lines 22. Consequently, it is possible to prevent an inspection error caused by a contact failure between the wiring portions 300R, 300G, 300B and the data lines 22, so that the image display inspection can be appropriately conducted.

### 2 Second Exemplary Embodiment

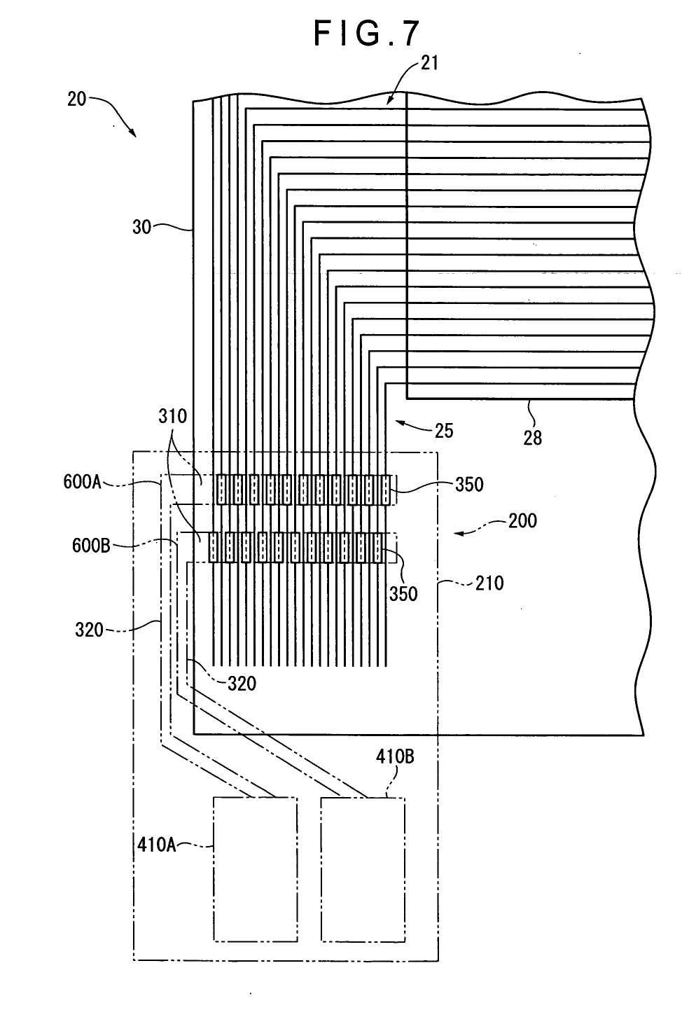

Next, a second exemplary embodiment of the invention will be described with reference to the FIG. 7. The second exemplary embodiment has similar basic arrangements as the first exemplary embodiment, but relates to an inspection probe that is connected with scanning lines.

In FIG. 7, the liquid crystal display panel 20 has the scanning lines 21 in rows. All the scanning lines 21 are drawn to the left in FIG. 7 and then extended downward to align in parallel to each other. The portion where the scanning lines 21 are aligned in parallel is the drawing portion 25.

The inspection probe 200 has the board 210, two wiring portions 600A, 600B, and signal input pads 410A, 410B.

The wiring portions 600A and 600B are respectively an odd wiring portion 600A and an even wiring portion 600B, which are arranged in this order from above.

The wiring portions 600A and 600B are same as the first exemplary embodiment in that the respective wiring portions 600A and 600B have the communication wiring 330, the insulating film 340 and the contacting sections 350 in the cross section structure in addition to the main shaft section 310 and the coupling shaft section 320.

The odd wiring portion 600A is in contact with odd scanning lines 21, while the even wiring portion 600B is in contact with even scanning lines 21. The pitch of the contacting sections 350 provided to the wiring portions 600A, 600B is twice as large as the pitch of the scanning lines 21.

The positions of the contacting sections 350 of the even wiring portion 600A are displaced from the positions of the contacting sections 350 of the odd wiring portion 600B by a width of one data line, such that the contacting sections 350 of the even wiring portion 600B contact the odd scanning lines 21 at the same time when the contacting sections 350 of the odd wiring portion 600A contact the odd scanning lines 21.

The signal input pads 410A and 410B are respectively the odd signal input pad 410A and the even signal input pad 410B, the odd signal input pad 410A being in connection with the odd wiring portion 600A and the even signal input pad 410B being in connection with the even wiring portion 600B.

The odd signal input pad 410A and the even signal input pad 410B are respectively input with signals of opposite phases from the inspection checker 500.

In the arrangement, when connecting the inspection probe 200 with the scanning lines 21, the inspection probe 200 is pressed on the scanning lines 21 from above such that the main shaft sections 310 of the wiring portions 600A and 600B become orthogonal to the scanning lines 21. Accordingly, the contacting sections 350 of the odd wiring portion 600A contact the odd scanning lines 21, while the contacting sections 350 of the even wiring portion 600B contact the even scanning lines 21.

Then, the inspection signals are sent to the wiring portions 600A and 600B from the inspection checker 500 via the signal input pads (odd signal input pad 410A, even signal input pad 410B).

Since the odd wiring portion 600A and the even wiring portion 600B are respectively input with the inspection signals of opposite phases, the odd scanning lines 21A and the even scanning lines 21B are also respectively input with the inspection signals of the opposite phases.

The inputs of the inspection signals light the liquid crystal display panel 20 on, and thereby the image display inspection is conducted by checking for any defect such as a leakage between the odd scanning line 21 and the even scanning line 21.

According to the second exemplary embodiment having the above-described arrangement, the similar functions and advantages as the first exemplary embodiment can be obtained in the inspection of the scanning lines.

Modification 1

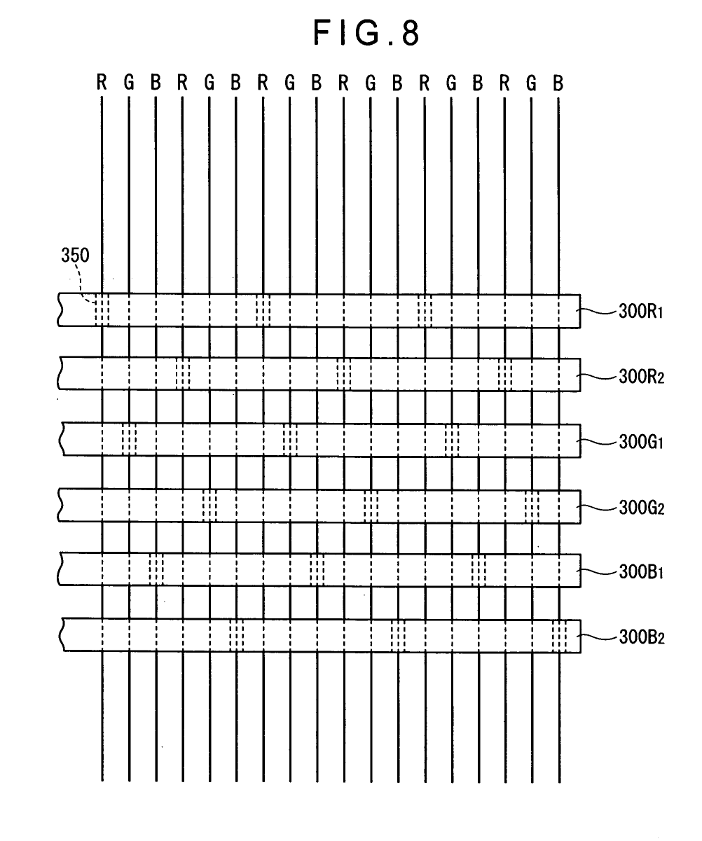

Next, a modification 1 of the invention will be described with reference to the FIG. 8.

Basic arrangements of the modification 1 are similar to those of the first exemplary embodiment. One difference is that six wiring portions are provided in the modification.

In the first exemplary embodiment, one red wiring portion 300R contacts so as to be connected with all the red data lines 22R, and the inspection signals are collectively input in all the red data lines 22R by the one red wiring portion 300R.

On the other hand, in the modification 1, two wiring portions are provided for each color (R, G, B). The respective wiring portions have the contacting sections 350 to contact with every two data lines of a corresponding color.

For example, two red wiring portions are provided. A first red wiring portion 300R1 and a second red wiring portion 300R2 respectively have the contacting sections 350 that contact with every two red data lines 22R.

Similarly, a first green wiring portion 300G1 and a second green wiring portion 300G2 respectively have the contacting sections 350 that contact every two green data lines 22G, while a first blue wiring portion 300B1 and a second blue wiring portion 300B2 respectively have the contacting sections 350 that contact with every two blue data lines 22B.

According to the arrangement, two wiring portions are provided for the data lines of each color (22R, 22G, or 22B), so that the data lines 22R, 22G and 22B can be divided into six groups. The inspection signals can be input for each group of the data lines 22 connected with a common wiring portion in the image display inspection, thereby presenting an advantage that a position where a defect occurs can be more specifically identified compared to the arrangement in which the data lines 22 are simply classified by color like the first exemplary embodiment.

It should be noted that the invention is not limited to the above-described embodiments, and may be modified or improved as long as an object of the invention can be achieved.

The to-be-inspected optical panel of the inspection device according to the invention may not be a liquid crystal display panel, but various kinds of optical panels having scanning lines and data lines are also acceptable.

In the first exemplary embodiment, the inspection probe connected to the data lines is explained as an example, while in the second exemplary embodiment, the inspection probe connected to the scanning lines is explained as another example. However, as is obvious, one inspection probe may have both of a wiring portion to be connected with a data line and a wiring portion to be connected with a scanning line.

In providing contacting sections to the wiring portion of the inspection probe, the contacting sections may be arranged so as to contact every two signal lines (data lines, scanning lines) or every three signal lines. Obviously, the pitch of the signal lines in contact with the contacting sections may be variously changed based on a required precision of the image display inspection.

In the above embodiments, the image display inspection is explained using the liquid crystal display panel as an example. However, the inspection probe according to the invention can be used for inspecting, for instance, an electronics device in which signal lines such as a semiconductor are wired with a narrow pitch.

The invention can be applied to an inspection of optical panels or electronics devices in which signal lines are wired.

What is claimed is:

1. An inspection probe for inspecting characteristics of an electronics device having a plurality of signal lines and a drawing portion to which the plurality of signal lines are drawn to be disposed substantially in parallel with each other, the inspection probe being temporarily connected with the signal lines in inspecting the characteristics of the electronics device, the probe comprising:
a board;
a plurality of wiring portions provided on the board, the wiring portions extending for a predetermined length in a direction intersecting the drawing direction of the signal lines when the board is pressed to the drawing portion of the signal lines and being arranged in the drawing direction of the signal lines; and
contacting sections provided on the wiring portions at a predetermined pitch, the contacting sections being in contact with the signal lines to which a common inspection signal can be inputted when the wiring portions are pressed on the signal lines while being intersected therewith on the drawing portion of the signal lines to electrically connect the signal lines and the wiring portions.

2. An inspection probe for inspecting image display of an optical panel, the optical panel having: columns of pixels exhibiting common one of basic colors, the columns of pixels exhibiting different basic colors being arranged in a row direction in a predetermined order so that more than one basic color are used to display a color image; and a drawing section to which data lines provided to each column for actuating the pixels are drawn to be disposed substantially in parallel with each other, the inspection probe being temporarily connected with the data lines in inspecting the image display of the optical panel, the probe comprising:
a board;
a plurality of wiring portions provided on the board, the wiring portions extending for a predetermined length in a direction intersecting the drawing direction of the data lines when the board is pressed to the drawing portion of the data lines and being arranged in the drawing direction of the data lines; and
contacting sections provided on the wiring portions at a predetermined pitch, the contacting sections being in contact with the signal lines to which common inspection signal can be inputted when the wiring portions are pressed on the signal lines while being intersected therewith on the drawing portion of the signal lines to electrically connect the signal lines and the wiring portions.

3. The inspection probe according to claim 2, wherein
the wiring portions are provided by a number corresponding to the number of the basic colors, and
the contacting sections provided on one of the wiring portions are positioned in correspondence with the data lines of common one of the basic colors.

4. The inspection probe according to claim 2, wherein
the wiring portion has a communication wiring for signals; and an insulation covering that insulatively covers the communication wiring, and
the contacting section is formed as a projection protruding from the communication wiring and the insulation covering covers the wiring portion except for an area occupied by the contacting sections.

5. The inspection probe according to claim 2, wherein
the basic colors are red, blue and green, and the optical panel has a sequential repetition of wiring of red data lines for driving red pixels, blue data lines for driving blue pixels and green data lines for driving green pixels,
the wiring portions include a red wiring portion to be in common continuity with all the red data lines, a blue wiring portion to be in common continuity with all the blue data lines, and a green wiring portion to be in common continuity with all the green data lines,
the red wiring portion has the contacting sections positioned in correspondence with an allocation pitch of the red data lines,
the blue wiring portion has the contacting sections positioned in correspondence with an allocation pitch of the blue data lines, and
the green wiring portion has the contacting sections positioned in correspondence with an allocation pitch of the green data lines.

6. An inspection probe for inspecting image display of an optical panel having a drawing portion to which common scanning lines for driving pixels for each row are drawn to be disposed substantially in parallel with each other, the inspection probe being in temporal contact with the scanning lines in inspecting in the image display of the optical panel, the probe comprising:
a board;
a plurality of wiring portions provided on the board, the wiring portions extending for a predetermined length in a direction intersecting the drawing direction of the scanning lines when the board is pressed to the drawing portion of the signal lines and being arranged in the drawing direction of the scanning lines; and
contacting sections provided on the wiring portions, the contacting sections being in contact with the scanning lines to which a common inspection signal can be inputted when the wiring portions are pressed on the scanning lines while being intersected therewith on the drawing portion of the scanning lines to electrically connect the scanning lines and the wiring portions.

7. The inspection probe according to claim 6, wherein
the number of the wiring portions is two, and
the contacting sections provided on one of the wiring portions contact every two scanning lines to establish continuity between the scanning lines and the wiring portion.

8. An inspection device, comprising:
an inspection probe; and
an inspection signal transmitter that inputs an inspection drive signal to an optical panel via the inspection probe, wherein
the inspection probe for inspecting characteristics of an electronics device has a plurality of signal lines and a drawing portion to which the plurality of signal lines are drawn to be disposed substantially in parallel with each other, the inspection probe being temporarily connected with the signal lines in inspecting the characteristics of the electronics device, the probe having:
a board;
a plurality of wiring portions provided on the board, the wiring portions extending for a predetermined length in a direction intersecting the drawing direction of the signal lines when the board is pressed to the drawing portion of the signal lines and being arranged in the drawing direction of the signal lines; and
contacting sections provided on the wiring portions at a predetermined pitch, the contacting sections being in contact with the signal lines to which a common inspection signal can be inputted when the wiring portions are pressed on the signal lines while being intersected therewith on the drawing portion of the signal lines to electrically connect the signal lines and the wiring portions.

9. An inspection device, comprising:
an inspection probe; and
an inspection signal transmitter that inputs an inspection drive signal to an optical panel via the inspection probe, wherein
the inspection probe for inspecting image display of an optical panel has: columns of pixels exhibiting common one of basic colors, the columns of pixels exhibiting different basic colors being arranged in a row direction in a predetermined order so that more than one basic color are used to display a color image; and a drawing section to which data lines provided to each column for actuating the pixels are drawn to be disposed substantially in parallel with each other, the inspection probe being temporarily connected with the data lines in inspecting the image display of the optical panel, the probe having:
a board;
a plurality of wiring portions provided on the board, the wiring portions extending for a predetermined length in a direction intersecting the drawing direction of the data lines when the board is pressed to the drawing portion of the data lines and being arranged in the drawing direction of the data lines; and
contacting sections provided on the wiring portions at a predetermined pitch, the contacting sections being in contact with the signal lines to which a common inspection signal can be inputted when the wiring portions are pressed on the signal lines while being intersected therewith on the drawing portion of the signal lines to electrically connect the signal lines and the wiring portions.

10. The inspection device according to claim 9, wherein
the wiring portions are provided by a number corresponding to the number of the basic colors, and
the contacting sections provided on one of the wiring portions are positioned in correspondence with the data lines of common one of the basic colors.

11. The inspection device according to claim 9, wherein
the wiring portion has a communication wiring for signals; and an insulation covering that insulatively covers the communication wiring, and
the contacting section is formed as a projection protruding from the communication wiring and the insulation covering covers the wiring portion except for an area occupied by the contacting sections.

12. The inspection device according to claim 9, wherein
the basic colors are red, blue and green, and the optical panel has a sequential repetition of wiring of red data lines for driving red pixels, blue data lines for driving blue pixels and green data lines for driving green pixels,
the wiring portions include a red wiring portion to be in common continuity with all the red data lines, a blue wiring portion to be in common continuity with all the blue data lines, and a green wiring portion to be in common continuity with all the green data lines,
the red wiring portion has the contacting sections positioned in correspondence with an allocation pitch of the red data lines,
the blue wiring portion has the contacting sections positioned in correspondence with an allocation pitch of the blue data lines, and
the green wiring portion has the contacting sections positioned in correspondence with an allocation pitch of the green data lines.

13. An inspection device, comprising:
an inspection probe; and
an inspection signal transmitter that inputs an inspection drive signal in an optical panel via the inspection probe, wherein
the inspection probe for inspecting image display of an optical panel has a drawing portion to which common scanning lines for driving pixels for each row are wired and are drawn substantially in parallel with each other, the inspection probe being in temporal contact with the scanning lines in inspecting in the image display of the optical panel, the probe having:
a board;
a plurality of wiring portions provided on the board, the wiring portions extending for a predetermined length in a direction intersecting the drawing direction of the scanning lines when the board is pressed to the drawing portion of the signal lines and being arranged when the board is pressed on the drawing portion of the scanning lines and being arranged in the drawing direction of the scanning lines; and
contacting sections provided on the wiring portions, the contacting sections being in contact with the scanning lines to which a common inspection signal can be inputted when the wiring portions are pressed on the scanning lines while being intersected therewith on the drawing portion of the scanning lines to electrically connect the scanning lines and the wiring portions.

14. The inspection device according to claim 13, wherein
the number of the wiring portions is two, and
the contacting sections provided on one of the wiring portions contact every two scanning lines to establish continuity between the scanning lines and the wiring portion.

15. An inspection method of an optical panel, comprising:
connecting an inspection probe with the optical panel; and
inputting an inspection drive signal to the optical panel via the inspection probe, wherein
the inspection probe for inspecting characteristics of an electronics device has a plurality of signal lines and a drawing portion to which the plurality of signal lines are drawn to be disposed substantially in parallel with each other, the inspection probe being temporarily connected with the signal lines in inspecting the characteristics of the electronics device, the probe having:
a board;
a plurality of wiring portions provided on the board, the wiring portions extending for a predetermined length in a direction intersecting the drawing direction of the signal lines when the board is pressed to the drawing portion of the signal lines and being arranged in the drawing direction of the signal lines; and
contacting sections provided on the wiring portions at a predetermined pitch, the contacting sections being in contact with the signal lines to which a common inspection signal can be inputted when the wiring portions are pressed on the signal lines while being intersected therewith on the drawing portion of the signal lines to electrically connect the signal lines and the wiring portions.

16. An inspection method of an optical panel, comprising:
connecting an inspection probe with the optical panel; and inputting an inspection drive signal to the optical panel via the inspection probe, wherein
the inspection probe for inspecting image display of an optical panel has: columns of pixels exhibiting common one of basic colors, the columns of pixels exhibiting different basic colors being arranged in a row direction in a predetermined order so that more than one basic color are used to display a color image; and a drawing section to which data lines provided to each column for actuating the pixels are drawn to be disposed substantially in parallel with each other, the inspection probe being temporarily connected with the data lines in inspecting the image display of the optical panel, the probe having:
a board;
a plurality of wiring portions provided on the board, the wiring portions extending for a predetermined length in a direction intersecting the drawing direction of the data lines when the board is pressed to the drawing portion of the data lines and being arranged in the drawing direction of the data lines; and
contacting sections provided on the wiring portions at a predetermined pitch, the contacting sections being in contact with the signal lines to which a common inspection signal can be inputted when the wiring portions are pressed on the signal lines while being intersected therewith on the drawing portion of the signal lines to electrically connect the signal lines and the wiring portions.

17. The inspection method of the optical panel according to claim 16, wherein
the wiring portions are provided by a number corresponding to the number of the basic colors, and
the contacting sections provided on one of the wiring portions are positioned in correspondence with the data lines of common one of the basic colors.

18. The inspection method of the optical panel according to claim 16, wherein
the wiring portion has a communication wiring for signals; and an insulation covering that insulatively covers the communication wiring, and
the contacting section is formed as a projection protruding from the communication wiring and the insulation covering covers the wiring portion except for an area occupied by the contacting sections.

19. The inspection method of the optical panel according to claim 16, wherein
the basic colors are red, blue and green, and the optical panel has a sequential repetition of wiring of red data lines for driving red pixels, blue data lines for driving blue pixels and green data lines for driving green pixels,
the wiring portions include a red wiring portion to be in common continuity with all the red data lines, a blue wiring portion to be in common continuity with all the blue data lines, and a green wiring portion to be in common continuity with all the green data lines,
the red wiring portion has the contacting sections positioned in correspondence with an allocation pitch of the red data lines,
the blue wiring portion has the contacting sections positioned in correspondence with an allocation pitch of the blue data lines, and
the green wiring portion has the contacting sections positioned in correspondence with an allocation pitch of the green data lines.

20. An inspection method of an optical panel, comprising:
connecting an inspection probe with the optical panel; and
inputting an inspection drive signal to the optical panel via the inspection probe, wherein
the inspection probe for inspecting image display of an optical panel has a drawing portion to which common scanning lines for driving pixels for each row are drawn to be disposed substantially in parallel with each other, the inspection probe being in temporal contact with the scanning lines in inspecting in the image display of the optical panel, the probe having:
a board;
a plurality of wiring portions provided on the board, the wiring portions extending for a predetermined length in a direction intersecting the drawing direction of the scanning lines when the board is pressed to the drawing portion of the signal lines and being arranged in the drawing direction of the scanning lines; and
contacting sections provided on the wiring portions, the contacting sections being in contact with the scanning lines to which a common inspection signal can be inputted when the wiring portions are pressed on the scanning lines while being intersected therewith on the drawing portion of the scanning lines to electrically connect the scanning lines and the wiring portions.

21. The inspection method of the optical panel according to claim 20, wherein
the number of the wiring portions is two, and the contacting sections provided on one of the wiring portions contact every two scanning
lines to establish continuity between the scanning lines and the wiring portion.
